(19) United States
(12) Patent Application Publication
(10) Pub. No.: US 2021/0092875 A1
(43) Pub. Date: Mar. 25, 2021

(54) MOBILE DATA CENTER AND METHOD OF OPERATING THE SAME

(71) Applicant: ENVION AG, Baar (CH)

(72) Inventor: Julian HELLMANN-REGEN, Berlin (DE)

(73) Assignee: ENVION AG, Baar (CH)

(21) Appl. No.: 16/760,403

(22) PCT Filed: Oct. 31, 2018
(86) PCT No.: PCT/EP2018/079839

§ 371 Date: Jul. 22, 2020

(30) Foreign Application Priority Data
Oct. 31, 2017 (DE) 10 2017 125 540.0
Nov. 3, 2017 (DE) 10 2017 125 769.1
Mar. 27, 2018 (DE) 10 2018 107 346.1

(51) Int. Cl. H05K 7/20; H05K 7/14; G06F 1/18; G06F 1/20

(52) U.S. Cl. CPC H05K 7/20745; H05K 7/1497; H05K 7/20836; G06F 1/206; G06F 1/181

(57) ABSTRACT

Mobile data center (10) comprising a plurality of computing modules (38, 40) to be air-cooled, a container (12) with an inner chamber for housing the plurality of computing modules, said container having four outer side walls, a bottom wall and a top wall, a plurality of air inlets (30, 32) to the inner chamber, at least two fans (34, 36) arranged for creating an air pressure gradient inside said inner chamber, and piping (52) arranged for guiding air through the inlets to the computing modules to be air-cooled when said air pressure gradient is created.

### TECHNICAL FIELD

The application relates to a mobile data center and a method of operating the same. The application also relates to a container for a mobile data center and the use of a modified ISO freight container for establishing a mobile data center. The application also discloses a use of a mobile data center for heating purposes.

### TECHNICAL BACKGROUND

Mobile, i.e. transportable data centers having large computing capacities are known in the art, for example from WO 2011/038348 A1, which discloses a mobile data center comprised of so called “data center modules”, one or more “electrical modules” coupled to the data center modules and one or more “air handling modules” coupled to the data center modules, each air handling module comprising at least one fan for blowing air into the air handling module. In operation, the air blown into an air handling module flows into a data center module associated with the respective air handling module. Like a personal computer, which has its own fan, in a preferred embodiment each data center module is provided with its own air handling module and hence each data center module has a fan designated to it. The modules have a rather open structure allowing air to flow from an air handling module via an air opening into a data center module and to flow via a return air opening from the data center module back into the air handling module in a rather random manner without specific ducts or guiding means. It has turned out that this way of cooling is not fully satisfactory in terms of energy efficiency and cooling capacity.

In order to improve the mobile data center known from WO 2011/038348 A1 in particular with respect to cooling, DE 20 2013 100 519 U1 proposes to install a raised floor in a container, like a standard twenty foot ISO freight container, to install a plurality of air conditioning modules between the raised floor and the floor of the container, and to install racks for computers on the raised floor so that they separate a cold aisle from a hot aisle. In operation, air is recirculated in the container from the hot aisle through the air conditioning modules to the cold aisle and through the racks of computers back to the hot aisle.

While the known mobile data centers are transportable and also allow customization for example with respect to computing power, it has turned out that cooling is still a challenge. If a computing module has its own fan, failure of that fan can lead to failure of the computing module. Cooling the air used for cooling the computing equipment in a data center requires additional devices like heat exchangers, heat pumps, compressors for refrigerants etc., each increasing costs of manufacture, operating and maintenance. Moreover, if liquid coolants are used, special safety precautions have to be taken to protect the computing and other electrical equipment installed in a data center from getting into contact with liquid that could cause severe damage to the computing and other electrical equipment.

Generally, cooling mobile or even immobile data centers is not trivial, and numerous attempts to improve the cooling have been made. Methods and systems for cooling data centers by air are for example disclosed in DE 10 2015 001 845 A1, DE 20 2016 105 002 U1 and EP 2 352 953 B1. Methods and systems using liquid coolants are for example disclosed in DE 20 2016 107 445 U1, WO 2011/082790 A1 and DE 11 2011 103 570 T5.

### SUMMARY

Although the known mobile data centers work quite well for some applications, there is room for improvement of the cooling with respect to failure safety, energy efficiency, costs of manufacturing, operating costs and costs of maintenance. It is therefore an object of the invention to provide a mobile data center having an improved cooling, and to provide a method of operating such data center more efficiently. The invention also aims at providing a container for a mobile data center, allowing to establish a mobile data center with improved cooling and having a very robust design in a very efficient way.

The objects are achieved by a mobile data center according to claim 1 respectively by a method according to claim 28. Independent claim 25 relates to a container for a mobile data center according to an embodiment of the invention. Independent claim 35 relates to the use of a standard ISO freight container for establishing a mobile data center. Claim 36 relates to the use of a mobile data center for heating purposes. The dependent claims relate to advantageous embodiments and implementations of the respective independent claims.

Surprisingly, it has turned out that multiple advantageous synergistic effects can be achieved by arranging computing modules in an inner chamber of a mobile container, providing the inner chamber with a plurality of air inlets and with piping directing air from the inlets to the computing modules, and creating an air pressure gradient, i.e. a pressure difference between the ambient air and the air inside the inner chamber such that the air pressure in the inner chamber is lower than the ambient air pressure. In contrast to for example complete buildings, it is rather simple to seal a corresponding inner chamber of a container such that air enters the inner chamber during operation basically only via the provided air inlets. The piping ensures that air entering the container during operation is not randomly distributed in the inner chamber, but is led onto the computing modules to be cooled. Quite surprisingly, experiments have shown that fans having a rather low power consumption are, due to the efficient sealing and air ducting of the inner chamber, perfectly sufficient to create an air pressure gradient inside the inner chamber that in turn leads to a sufficient flow of air into the inner chamber through the air inlets for cooling the computing modules. For example, it has turned out that already two fans, each having a maximum power consumption of only 250 W, are sufficient for creating inside a standard twenty foot ISO freight container such air pressure gradient that computing modules arranged in the container having a power consumption in the region of 40.000 to 80.000 W can be efficiently cooled, leading to an astonishing power usage effectiveness (PUE) in the region of 1.02 to 1.01, the PUE being the total amount of energy used by the data center divided by the energy delivered to the computing equipment.

It should be noted that the term “computing equipment” as used herein refers to computing modules including supplementary hardware such as cables, power supplies etc. The term “computing module” refers to all types of electronic equipment actually performing computing, such as circuit boards like for example graphic cards equipped with multiple electronic devices, an array of such cards or boards or more complex assemblies of electronic devices such as servers, computers and devices generally known as miners, in particular so called ASIC miners, which are used in particular for block chain operations, or GPU miners, i.e. arrangements of multiple graphic cards and respective hardware for controlling the graphic cards, which are generally used for complex calculations needed e.g. for rendering movies, but which of course can also be used due to their computing power for block chain calculations.

Typically, the computing modules used in embodiments of the invention are ASIC and/or GPU miners, having a high power consumption. Traditionally, each such miner is equipped with its own fan for cooling the electronic equipment. It has surprisingly turned out that instead of using individual fans for each miner, using just two fans in or on the container provides sufficient and failure safe cooling at much lower costs. In case the individual fan of a miner fails, the miner is typically shut down to prevent damage through overheating. According to embodiments of the invention, two fans are provided and are typically operated in parallel at less than their maximum power. If one of the fans fails, the other fan can be operated at higher power and ensure sufficient cooling of the equipment housed in the container. Corresponding control equipment may be provided that in case one fan fails automatically creates an alarm signal that can easily be communicated e.g. wirelessly via a small mobile communication device to an operator, who may then arrange for maintenance or repair of the fan. Providing two lager fans is also cheaper and less power consuming than providing numerous smaller fans at each computing module. However, depending on the type of computing module it may not be necessary to remove an individual fan already provided on the computing module, as it may be more costly to remove such fan than keeping it. Such fan may be disabled or may be even be kept enabled, but usually the air directed form the air inlets in the container via the piping to the computing module provides sufficient cooling. As computing modules equipped with individual fans typically comprise hardware for controlling these fans, the fans will, if at all, advantageously run only at very low power consumption rates.

Whereas it is possible to provide fewer air inlets to the inner chamber than computing modules, and to provide piping for distributing the air entering the inner chamber via the air inlets to the computing modules, in a preferred embodiment each computing module has at least one air inlet in a wall of the inner chamber exclusively associated with it. Depending on the type of computing module, the module may even have more than one air inlet exclusively associated with it.

The inner chamber of the container may simply be defined by the outer walls of the container. In such case, the air inlets of the inner chamber may simply be provided in one wall of the container, which may be useful in cases where the container is placed close to other containers or close to walls. In a preferred embodiment, the air inlets are distributed in different side walls of the container so that the piping necessary to lead air from an air inlet to a respective computing module can be kept short.

It is also possible to equip the container with at least one inner partition wall defining a partition between the inner chamber and an air intake chamber formed in the container. If a partition wall is provided, the air intake chamber may be formed by the partition wall, one outer side wall and adjacent portions of two other outer sidewalls, the bottom and the top wall and may comprise at least one air intake opening having a larger effective intake area than the single air inlets in the inner chamber.

The air inlets of the inner chamber can be formed by simple openings. However, in a preferred embodiment at least some of the air inlets are formed by elbow pipe pieces arranged with their outer end facing downwards on the outside of the container. This hampers the intrusion of rain or snow into the container when the container is placed outdoors.

In a preferred embodiment at least some of the computing modules are arranged in their own housings, each such housing having an air inlet and an air outlet, said air inlet directly connected with at least one of the air inlets of the inner chamber and said air outlet communicating with the inner chamber.

In a preferred embodiment, the container is made of so called weathering steel, i.e. a steel alloy forming a stable rust-like protective layer when exposed to weather. The container may be designed to be stackable with other containers of the same construction type. In a particularly preferred embodiment, the container is a standard ISO freight container, in particular a twenty foot ISO freight container or a forty foot ISO freight container. This has multiple advantages. For example, due to the standardization, transportation of a mobile data center established with such container is fairly simple. The containers are very stable and can easily be stacked on top of each other.

It is possible to install the at least two fans in or on the same wall of the container, even in or on the top wall or in certain cases in or on the bottom wall, for example when the air blown out of the container shall be introduced in an air channel system e.g. of a residential building or a swimming pool for heating purposes. In such case, the outer ends of the fans may terminate in a standardized piping section like a 500 mm tube for easy connection with corresponding parts of a building's heating system. While the fans may be integrated in one or more of the walls or may be attached to the inside or the outside of one or more of the walls, they may also be placed e.g. on the floor of the container. However, arranging the fans close to or even in a wall reduces the amount of piping necessary for enabling air flow form the inner chamber to the outside of the container. In case the inner chamber is formed by the outer container walls, no such piping at all is necessary in case the fans are attached to or integrated in one or more of the container walls.

In a preferred embodiment, the fans are arranged in or attached to opposite side walls of the container. This ensures an even distribution of the air pressure gradient that is established in the inner chamber during operation of the fans, and also facilitates that containers can be stacked on top of each other.

In the inner chamber, at least some of the computing modules may advantageously be arranged on racks, each rack preferably being arranged on rails so as to be movable along the rails in the container. Preferably, two units of racks on rails may be provided in the inner chamber, each unit comprising preferably three to four racks, each rack comprising preferably three to four shelves, said shelves being preferably offset in height with respect to the shelves of a neighboring rack.

In a preferred embodiment, the mobile data center comprises data communication equipment, in particular satellite communication equipment including an antenna. Such antenna may be retractably arranged on the top wall of said container. Generally, a mobile data center according to an embodiment of the invention will be designed to be remote-controlled, operating mostly fully automatically and in remote areas. A typical application of such data center is performing complex and power consuming computations such as block chain calculations or movie rendering. Whether or not such computations are profitable strongly depends on the price of electric energy. As there are numerous, yet sometime remote locations, for example at hydroelectric power plants, where at least during certain daytimes electric energy, which is generally difficult to store, can be obtained at low costs, mobile data centers according to embodiments of the invention may be located at such locations and may be operated during times when energy costs are down. Once started, a data center performing calculations of the type mentioned typically does not need permanent access to the internet or to any other external source. Rather, it may perform the calculations and just sent out the results, which generally does not require high data connection rates. In case multiple mobile data centers are provided, they may be connected to share the communication equipment.

Further objects, details and advantages of the invention will become apparent from the following non-limiting description of preferred embodiments and implementations in conjunction with the accompanying drawing, which comprises seven figures.

### BRIEF DESCRIPTION OF THE DRAWING

FIG. 1 is a schematic diagram of a mobile data center housed in a standard twenty foot ISO freight container in a perspective view.

FIG. 2 is a schematic diagram showing the front side of the data center according to FIG. 1 in plan view.

FIG. 3 is a schematic diagram showing in a perspective view some of the parts of the mobile data center arranged in resp. attached to the container shown in FIG. 1.

FIG. 4 is a schematic diagram showing in a perspective view some of the parts of a mobile data center to be arranged in resp. attached to a container, the mobile data center comprising multiple ASIC miners.

FIG. 5 is a schematic diagram showing in a perspective view some of the parts of a mobile data center to be arranged in resp. attached to a container, the mobile data center comprising multiple GPU miners.

FIG. 6 is a schematic diagram showing the parts according to FIG. 5 in plan view.

FIG. 7 is a schematic diagram showing a section of a container according to an embodiment of the invention provided with an inner partition wall separating an inner chamber from an air intake chamber.

### DETAILED DESCRIPTION OF PREFERRED EMBODIMENTS AND IMPLEMENTATIONS

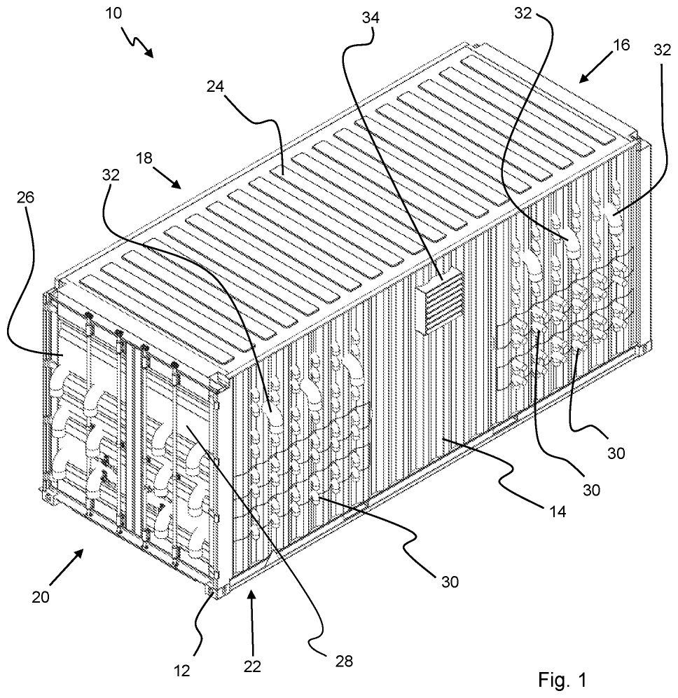

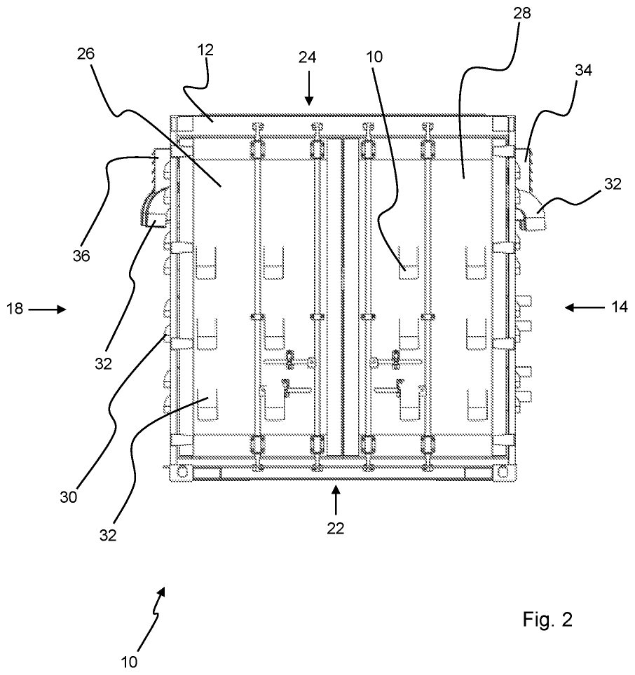

FIGS. 1 and 2 show very schematically a first embodiment of a mobile data center 10 housed in a standard twenty foot ISO freight container 12 having four outer side walls 14, 16, 18 and 20, a bottom wall 22 and a top wall 24, the walls directly defining an inner chamber.

One of the side walls, in this case side wall 20, is formed by two door wings 26 and 28. It should be noted that as a side wall can be formed by door wings or may comprise at least one door, the term “in a wall of the container” as used in this description and in the claims also denotes that something is provided in a door wing or a door that may be present in a wall of the container.

The container 12 is provided with numerous air inlets 30 and 32, of which only some are provided with reference numbers for sake of clarity. As in this embodiment the outer walls of the container form the inner chamber, i.e. the inside of the container 12 is the inner chamber, the air inlets 30 and 32 form air inlets to the inner chamber. In this embodiment, each air inlet 30 and 32 comprises an elbow pipe piece arranged with its outer end facing downwards on the outside of the container 12.

The air inlets 30 and 32 may be provided with wire meshes and/or filters depending on the ambient conditions, in which the container 12 shall be placed. Whereas wire meshes generally do not influence the air flow to a substantial degree, filters such as sand or dust filters may obstruct the air flow and hence it may be necessary to increase the air pressure difference between the inside and the outside of the container to ensure the same air flow rate in case the air inlets are provided with such filters compared to a case where no such filters are present. Creating such air flow will be described later. Embodiments of the invention advantageously allow the user of the mobile data center to decide depending on the ambient conditions, whether or not filters shall be foreseen. In some cases, it may be fully sufficient to protect the equipment inside the container from insects and particles by providing the air inlets with fine wire meshes that do not substantially hinder the air flow. Such wire meshes and/or filters may be provided at any convenient location, e.g. at the free end of the elbow pipes or in the air inlets or they may from a transition from an air inlet to the piping distributing the air entering the container.

At least some of the air inlets 30 and 32 and/or some of the piping may further be provided with automatically controllable throttle valves for controlling the air flow through the respective air inlets and the piping, which may be useful in certain circumstances as will be described later.

Two fans 34 and 36 are arranged on opposite side walls 14 and 18 of the container 12 for creating an air pressure gradient in the container 12. For a typical twenty foot ISO freight container, it has turned out that two fans having propellers with diameters in the region of 400 to 500 mm and a maximum power in the region of 150 to 400 W such that each fan may create a volume flow in the region of about 4.000 to 8.000 m³/h are perfectly sufficient for ensuring sufficient cooling of computing modules typically arranged in the container, provided that the computing modules are arranged according to the invention such that the air entering the container 12 via the air inlets 30 respectively 32 is directed to the computing modules. This arrangement will be described later.

In the embodiment shown in FIGS. 1 and 2, the air inlets 30 and 32 have different cross-section areas and hence lead to different volume flows. The embodiment shown is a kind of “universal” container that can be equipped with different computing modules having different cooling necessities. Depending on the actual arrangement of computing modules inside the container, some of the air inlets may be closed. In this respect, the invention advantageously provides different options. For example, if the computing equipment in the container will be changed often, it is useful to provide the container with air inlets of different sizes, i.e. different cross section areas allowing different volume flows and to provide closing means for example structure like throttle valves, which may be manually or preferably automatically controlled, for closing and opening only those air inlets, that are actually needed for cooling the computing equipment, in particular the computing modules currently installed in a container, or even only those computing modules that are in operation. Instead of throttle valves, it is of course also possible to simply close and open air inlets via respective lids.

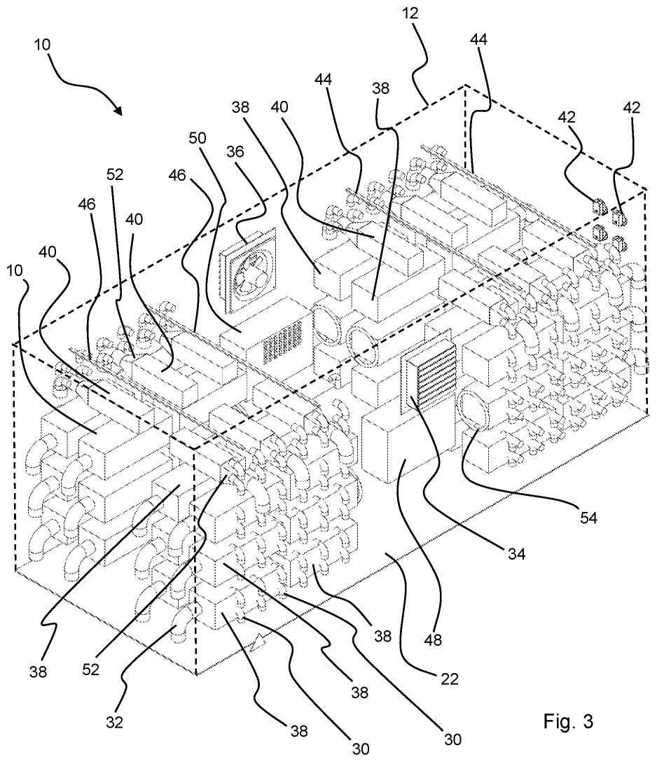

FIG. 3 is a very schematic drawing of some of the equipment, in particular computing modules 38 and 40, of which only some are provided with reference numbers for sake of clarity, arranged in and attached to the container. Basically, the drawing shows a mobile data center 10 according to FIG. 1, in which however the four side walls and the top wall of the container indicated by dashed lines have been made transparent. Racks with shelves, on which the computing modules 38 are arranged, are not shown in FIG. 3. Hence, equipment placed on racks, like the computing modules 38 and 40, or attached to the walls of the container like the fans 34 and 36, the air inlets 30 and 32, power connectors 42, rails 44 and 46 for moving the racks as well as power distribution and control units 48 and 50, seems to float in space in the drawing, whereas in fact this equipment is either supported by the walls of the container or by the shelves. Also, of the piping provided in the container for guiding air from the air inlets 30 and 32 to the computing modules only some is shown.

In this embodiment, four groups of three computing modules 40 are arranged in the four upper corner areas of the container. These computing modules 40 may be ASIC miners, which typically come in individual cuboid housings such as the ones shown in the drawing. The housings have openings on two opposite end faces sides for blowing air through the housings. In operation, ambient air is introduced into the housings on one end through a respective one of the air inlets 32 and piping in form of a funnel like adapter 52. The air leaves each housing on the respective other end, which communicates with the inside of the container.

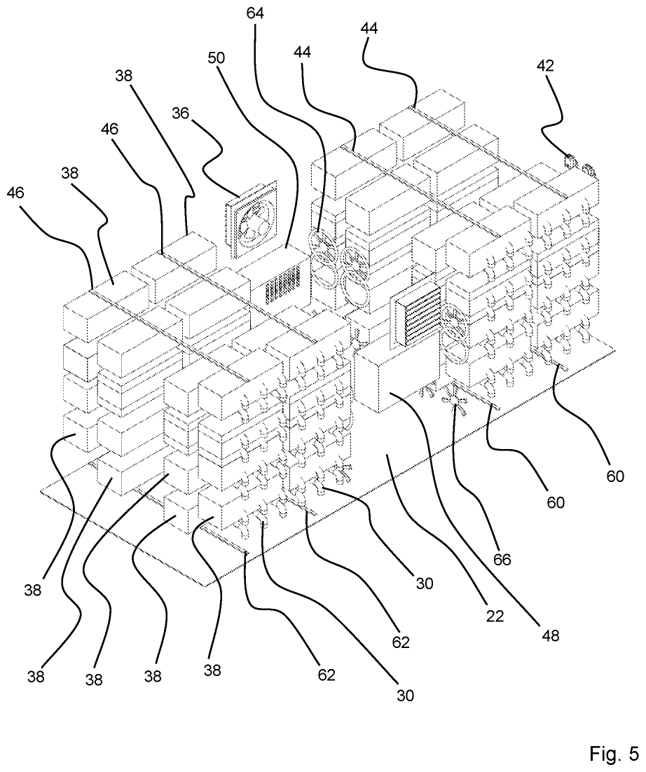

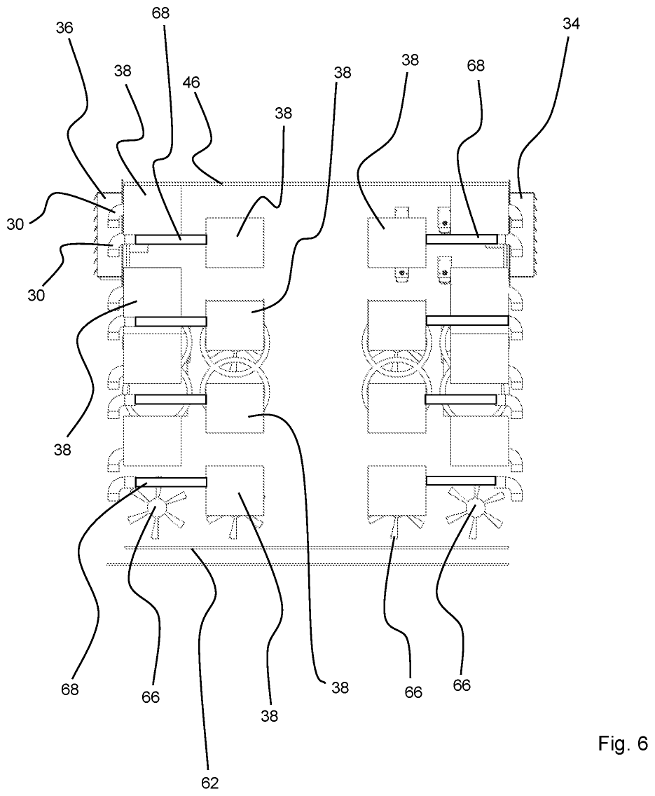

Eight groups of six computing modules 38 are arranged on eight racks, each rack comprising three shelves. Pairs of two computing modules 38 are arranged with their main axis aligned on each shelve. As explained, neither the racks nor the shelves are shown. What is shown are the upper pairs of rails 44 and 46, each pair guiding a group of four racks, which can be moved along the rails in a known fashion by turning a very schematically depicted handwheel 54 provided on each rack. Such rack systems are typically used in archives and libraries and can advantageously be used in the data center to move the racks along the rails for maintenance and installation purposes. In a preferred embodiment, the shelves of each rack are slightly shifted in height with respect to the shelves of a neighboring rack, which ensures that if computing modules of the same construction type are arranged on neighboring shelves, the hot regions of neighboring computing modules are slightly shifted. An example of such arrangement is depicted in FIGS. 5 and 6.

In an actual embodiment, the computing modules 38 schematically indicated by cuboid boxes correspond to GPU miners, each miner comprising a plurality of graphic cards on a support. Unlike the drawing suggests, such GPU miners may not necessarily be provided in a separate housing, but may have a rather open structure. In such case, the air inlets 32 are not needed and each GPU miner is supplied with air via three air inlets 30. Typically, computing modules of this type will be directly connected to a plurality of air inlets of the container, in particular to two to four air inlets. The piping is such that airstreams parallel to the graphic cards are created.

Each graphic card has two main surfaces called sides, one of which being called the hot side, on which the electronic devices that during operation get hot are arranged, and the other one being called the cold side. In a preferred embodiment the graphic cards in such GPU miner are arranged in parallel such that where possible, two hot sides and two cold sides face each other while the distance between the hot sides of the cards is maximized and the distance between the cold sides is minimized, i.e. pairs of cards are arranged close together with their cold sides facing each other and their hot sides facing in opposite directions towards, if present, the hot sides of other cards further apart. In operation, air will mainly flow through the space created between the hots sides, and the space between the cold sides may even be closed for airstreams.

Of the piping used for guiding the air from the air inlets to the computing modules, only some is shown. For example, the air inlets arranged to form a second, a fourth and a sixth row of air inlets 30 as seen from the bottom wall 22 of the container look as if they would terminate either above or in one of the computing modules 38 placed on a rack close to the side wall of the container, in which the respective air inlets are provided. In fact, piping (not shown in FIGS. 3, 4 and 5) is provided to connect these air inlets with the computing modules in a second rack further apart from said side wall.

In this embodiment, the mobile data center comprises two power distribution and control units 48 and 50 from which power input via power connectors 42, of which only some are provided with reference numbers, arranged on the outside of the container is distributed to the fans 34 and 36, to the computing modules 38 and 40, and to any other electrical equipment that may be present in the mobile data center. The control units 48 and 50 preferably also comprise hardware for controlling the operation of the mobile data center, e.g. PID controllers for the fans and optionally also for the computing modules as it may in certain cases be advantageous not only to control the speed of the fans and hence the volume flow created but also to adjust the calculation speed and hence the power consumed and the heat created by the computing modules.

If throttle valves are provided for opening/closing at least certain air inlets, these throttle valves may also be controlled by the control unit 48 and 50 or remotely. For example, if a mobile data center is placed outdoors and it is via respective sensors or by an (remote) operator detected that there is heavy rain or a sand storm, it may be expedient to decrease the air pressure gradient in the container, i.e. to turn down the speed of the fans to prevent that humidity or sand is drawn into the container. To avoid overheating in such circumstances, as less cooling air will be directed to the computing modules, it is possible to decrease the computing power such that less heat is generated during operation of the computing modules.

In a preferred embodiment, respective PID controllers, in which e.g. the current temperature in the container and the air pressure difference between the inside of the container and the ambient air is input, may be set up to output values of voltage supplied to the fans to control the speed of their propellers and the computing power of the computing modules, e.g. by decreasing their hash rate, which is proportional to the head created by the computing modules. The power distribution may be controlled for example by small e.g. Linux-based server systems and chip-based microcontrollers.

The power connections of the individual power supply units of the computing modules may be controlled using a set of solid state relays that are triggered using e.g. the general purpose in-out pins of a server-connected control board or of a raspberry single-pcb-computer, which in turn are controlled e.g. using node.js-based applications and access via http-served dash boards.

The control units 48 and 50 may have a redundant layout, i.e. they may be designed and connected to back-up each other such that in case one of the units fails, the other may still be able to control the mobile data center and in particular the power distribution to the computing modules and to the fans.

The control units 48 and 50 preferably also comprise hardware for executing special startup and/or shutdown routines and maintenance operations such as for example an “air inlet cleaning mode”, in which the turning direction of the fans is reversed to increase the air pressure in the container and to blow air out of the container via the air inlets to free the air inlets and in particular any wire meshes and filters in the air inlets from particles and other impurities that may obstruct the air flow into the container. For this purpose, the mobile data center may be provided with sensors for measuring the air pressure gradient in the container, i.e. the difference between the air pressure inside the container and the ambient air. It is easy to determine which air pressure gradient will occur for a certain combination of open air inlets and certain operating speeds of the fans. Such data can either be represented in form of a calibration curve or in a look-up table.

Monitoring the air pressure gradient allows to determine anomalies and in particular to determine, when the gradient exceeds a certain threshold value, in case of which it may be assumed that the air flow into the container is obstructed for example by particles clogging the filters or wire meshes of the air inlets. In such case, the mentioned cleaning circle may be started and the fans may be run in reverse mode (i.e. in a mode, in which the turning direction of the fans is opposite to the turning direction in the standard operation mode, in which the fans are run to blow air out of the inner chamber) and be used to suck air into the inner chamber, hence reversing the airstream through the air inlets and blowing out clogging particles. Such cleaning circle may be executed fully automatically. It may be preset that a cleaning circle is run for predetermined time period, for example five minutes, after which the fans resume their normal mode of operation and air will be drawn into the container via the air inlets.

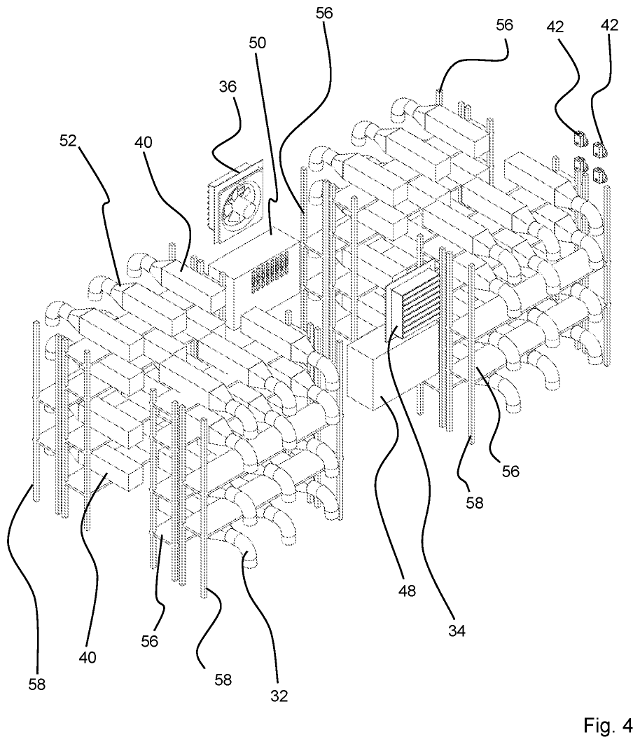

Similar to FIG. 3, FIG. 4 depicts equipment installed in respectively attached to a container for establishing a mobile data center. Similar or identical parts and structure are provided with the same reference numbers and reference is made to the description above. Only some of identical parts are provided with reference numbers.

In this embodiment, computing modules in form of ASIC miners 40 are arranged in the container, the walls of which are not shown. Each ASIC miner 40 is connected via respective piping, in particular a funnel like adapter 52 to one air inlet 32. In this respect, it should be noted that depending on the arrangement of the computing modules inside the container, the piping may simply consist in an elbow pipe piece provided in the container wall and forming an air intake. If the distance between the computing module to be air cooled and the container wall is longer, typically a pipe will guide air from the inlet to the respective computing module.

It should also be noted that the air inlets in the container walls may have other structures than the shown elbow pipe pieces and, depending on ambient conditions, may simply consist in holes in the container wall. One advantage of the invention is the flexibility, i.e. adjustability of its inner structure to different computing requirements.

Depending on the computing modules arranged in the container for establishing the mobile data center, the piping can fairly easy be adjusted such that air from the air inlets is guided to the computing modules to be cooled or to special parts of such computing modules. The piping may be set up using standard plastic tubes. In the embodiment shown in FIG. 4, the racks for placing the ASIC miners 40 are formed by shelves 56 supported by side supports 58.

In the embodiment shown in FIGS. 5 and 6, computing modules in form of GPU miners 38 are arranged in the container, of which only the bottom wall is shown. Again, similar or identical parts and structure are provided with the same reference numbers as used for the other figures and reference is made to the description above. Only some of identical parts are provided with reference numbers. FIG. 5 also depicts two pairs of lower rails 60 and 62 cooperating with the upper rails 44 respectively 46 for guiding in this embodiment two racks arranged in opposite ends of the container. Again, the racks themselves are not shown.

The GPU miners 38 are arranged on eight racks (not shown), each rack comprising four shelves (not shown), and two GPU miners 38 are arranged on each shelve, such that in total sixty four GPU miners 38 are arranged in the container. The racks are movable along the rails by turning respective handwheels 64. Optionally, as very schematically indicated by propellers 66 in the lower part of each rack, supplementary fans may be installed, which can create an airflow supporting the drawing out of hot air from the container. These supplementary fans may only be started in case the temperature in the respective areas of the container exceeds a certain maximum, and may generally run at low speed, hence not consuming substantive energy amounts. However, for most cases and ambient conditions no such fans are necessary.

Each GPU miner 38 is associated with three air inlets 30 either directly or via piping 68 schematically indicated in FIG. 6.

As is best seen in FIG. 6, the shelves (not shown) of the racks (not shown) are arranged such that they are shifted in height with respect to the shelves of a neighboring rack, such that the computing modules of one rack are not on the same height as the computing modules of a neighboring rack. For example, the shelves (not shown) of a rack disposed close to the left or the right side of the container in FIG. 6 are slightly higher than the respective shelves of the immediately neighboring rack, which not only allows to keep the piping 68 for guiding air to the computing modules 38 further apart from the side of the container fairly simple, but which also ensures that the hottest parts of each computing module are not placed completely adjacent to respective parts of a neighboring computing module.

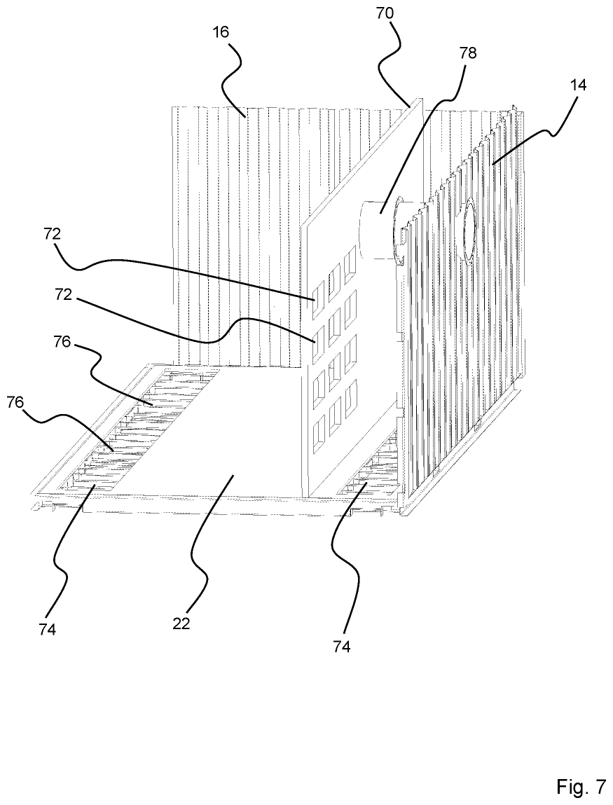

FIG. 7 shows a section of a container like the one shown in FIG. 1 having four outer side walls, of which only the side walls 14, 16 are shown, a bottom wall 22 and a top wall (not shown). The container is provided with two inner partition walls 70, of which only one is shown. With the two partition walls, three chambers are defined in the container, namely
one inner chamber surrounded by the partition walls 70, a part of the bottom wall 22, a part of the top wall (wall 24 in FIG. 1) a part of the side wall 16 and a part of its opposite side wall (the side wall 20 in FIG. 1), and
two air intake chambers, each surrounded by one of the partition walls 70, a part of the bottom wall 22, a part of the top wall (wall 24 in FIG. 1) a part of the side wall 16 and a part of its opposite side wall (the side wall 20 in FIG. 1), and one of the outer side walls 14 respectively its opposite outer side wall (18 in FIG. 1).

Each partition wall 70 is provided with numerous air inlets 72, via which in operation of the data center ambient air enters the inner chamber via the air intake chambers and is directed to the modules to be cooled as described above.

To allow ambient air to enter the air intake chambers, in this embodiment the bottom wall 22 has been provided with two large, rectangular cutouts 74 each adjacent to one of the side walls 14 and its opposite side wall (18 in FIG. 1). As the bottom wall of the container has (like all walls of the container) a corrugated structure, the cutout is made such that some supporting ribs 76 still remain. The cutouts may then be covered for example with one or two layers of metal grid, which may sandwich an air filtering material. Each cutout 74 functions as an air intake opening and has a larger effective intake area than the single air inlets 72 to the inner chamber. Again, two fans (not shown) are provided to blow out air from the inner chamber through piping 78 terminating at the outside of one of the outer sidewalls 14 and it opposite side wall (18 in FIG. 1). The piping may be connected for example to piping of a heating system for heating a building, a swimming pool or the like.

Although in this embodiment it must be ensured, for example by placing the container on supports, that sufficient ambient air can enter the air intake chambers, this embodiment has for certain environments and conditions advantages over the embodiment in which the walls of the container directly form the inner chamber. For example, the partition walls separate the “hot” inner chamber from at least two of the outer sidewalls and allow to maintain the general rather smooth outer appearance of a standard container without numerous visible air inlets. In this respect, it should be noted that while two partition walls running parallel to two side walls have been described above, it is possible to use only one partition wall or to use more than two, and to provide them for example parallel to the top and/or the bottom wall(s). Also, as during operation sound is created at the air inlets 72, embodiments with one or more air intake chambers and large air intake openings can lead to a reduction of the noise audible at the outside of the container. Another advantage is that the air inlets 72 even in dusty environments do not have to be provided with individual air filters as the ambient can already be filtered upon entering the air intake chamber(s), such that instead of multiple filters only a few large filter units need to be maintained. Like the air inlets mentioned above, the cutouts may be provided with automatically controllable throttle valves for example in form of adjustable fins for controlling the air flow through the cutouts.

In its simplest implementation, a method of operating a mobile data center according to an embodiment of the invention may comprise a step of operating the at least two fans to create a pressure gradient in the inner chamber causing ambient air to enter the inner chamber via the air inlets. Preferably, the operating status of each fan is monitored, i.e. it is monitored if each fan operates as intended. For this purpose, for example the power input of each fan or the speed of rotation of each propeller of each fan can be monitored and under normal circumstances each fan is operated as less than its maximum power. In case one of the fans fails or goes into an anomalous operating state, the other fan may be operated at higher power output to compensate the failing fan. Preferably, an alarm signal is created if it is detected that one of the fans is not operating normally and the signal is preferably automatically forwarded to an operator, who may then arrange for maintenance or repair of the fain.

Advantageously, the mobile data center may be provided with at least one, preferably more than one sensor for measuring at least one, preferably more than one of the following physical properties: temperature in the inner chamber, ambient temperature, air pressure in the inner chamber, ambient air pressure, humidity in the inner chamber and/or in certain air inlets, ambient humidity, and the method of operating the mobile data center may take into account the at least one, preferably more than one of the measured physical properties. For example, if it is detected that the air pressure gradient in the inner chamber exceeds a certain value, a cleaning circle as described above may be started automatically and the turning directions of the fans may be reversed.

If it is detected that the temperature in the inner chamber exceeds a certain maximum value although the fans already run at their maximum speed, the computing power of the computing modules may be turned down such that less heat will be created in the container. Likewise, if it is detected that the ambient air is quite humid for example due to heavy rain, or that there is a sand storm, computing power may be turned down such that less cooling is necessary and less air and accordingly less humidity or sand is drawn into the inner chamber or into the filters in the air inlets. In certain cases, the computing modules may even be switched off and the air inlets may be closed for example via throttle valves. Obviously, if the mobile data center is set up for operation under harsh ambient conditions, the fans of the container may be provided e.g. with adjustable rotor blades or other hardware allowing to close the fan openings in certain cases. In this respect, the invention advantageously allows the operator of a mobile data center to define his own criteria for operating the mobile data center under the respective ambient conditions that meet his requirements best.

The hardware and the method for operating the mobile data center may in particular provide a time shifted start of at least some of the computing models upon powering up the mobile data center and likewise a time shifted shutdown of at least some of the computing models upon powering down the mobile data center. Generally, due to the high total power consumption of the computing units arranged in the container, surge current protection is useful. In one embodiment and implementation, solid-state relays are used for activating the computing units. Upon powering up, all solid-state relays are off. After about ten seconds, a Linux-based server system and chip-based micro controllers are run up and ready. A start-up script is then automatically executed, randomly activating the solid-state relays for the computing modules, ensuring that not all computing modules receive power at the same time.

The powering up may also be done sequentially on a rack-by-rack and a computing-module-by-computing-module basis, i.e. power may be distributed to certain racks, which have their own rack-specific set of solid-state relays controlled by a micro controller allowing to switch on (or off) certain computing modules in the respective rack. Such automatic start-up hardware and method allow to safely connect standard plugs to the mobile data center without the need of special and expensive circuit breakers and ensures the versatility of the mobile data center to be plugged into virtually any sufficient power source. Likewise, hardware and method steps for automatically powering down the mobile data center are advantageously provided, ensuring that the computing modules are disconnected from power via shutting down all solid-state relays in a random or sequential order and not all at the same time, so that plugs can be removed safely without the danger of creating electric arcs inside the plugs.

Although it has turned out that the mobile data center according to an embodiment of the invention has an astonishing power usage effectiveness, the efficiency of the energy used and the environmental performance of the mobile data center can even be increased if the mobile data center is used for heating purposes such as for example heating a green house, a factory hall, a residential building, a swimming pool, a sports hall, a storehouse etc. Depending on the respective conditions, it is generally quite easy to either directly blow the air heated by the computing modules in the mobile data center into an air conducting system of a building or, in case of for example a factory hall, to simply place the mobile data center at a suitable position in the hall and use the air blown out of the mobile data center for heating purposes. In other environments, the hot air may be guided to heat exchangers and may for example be used for heating water. As the computing equipment is well protected in the container, it is easily possible to position the mobile data center where the hot air can conveniently be used.

1. Mobile data center comprising:
a plurality of computing modules to be air-cooled,
a container, said container comprising
an inner chamber for housing said plurality of computing modules, at least four outer side walls, a bottom wall and a top wall,
a plurality of air inlets to the inner chamber, said air inlets arranged in the side walls of the container, and
at least two fans for creating an air pressure gradient inside said inner chamber;
piping arranged for guiding air through the air inlets to the computing modules to be air-cooled when said air pressure gradient is created, and
a control unit controlling the operation of said at least two fans to create an air pressure gradient in said inner chamber causing ambient air to enter the inner chamber via said air inlets.

2. The mobile data center according to claim 1, wherein each computing module have/has at least one air inlet exclusively associated with it.

3. The mobile data center according to claim 1, wherein the air inlets are distributed in different outer side walls of the container.

4. The mobile data center according to claim 1, wherein each inlet is formed by an elbow pipe piece arranged with its outer end facing downwards on the outside of the container.

5. The mobile data center according to claim 1, further comprising at least one inner partition wall defining a partition between the inner chamber and an air intake chamber formed in the container, wherein at least some of the air inlets are distributed in the inner partition wall of the container.

6. The mobile data center according to claim 5, wherein said air intake chamber is formed by the partition wall, one outer side wall and adjacent portions of two other outer sidewalls, the bottom and the top wall and comprises at least one air intake opening having a larger effective intake area than the single air inlets to the inner chamber.

7. The mobile data center according to claim 1, wherein at least some of the computing modules are arranged in their own housings, each housing having an air inlet and an air outlet, said air inlet directly connected with at least one of the air inlets of the inner chamber and said air outlet communicating with the inside of the inner chamber.

8. The mobile data center according to claim 1, wherein the at least two fans are arranged in or attached to opposite side walls of the container.

9. (canceled)

10. Mobile data center according to claim 1, wherein said container is designed to be stackable with other containers.

11. Mobile data center according to claim 1, wherein said container is a standard ISO freight container, in particular a twenty foot ISO freight container or a forty foot ISO freight container.

12. (canceled)

13. (canceled)

14. The mobile data center according to claim 1, wherein at least some of the computing modules are ASIC miners or GPU miners.

15. Mobile data center according to claim 14, comprising ASIC miners, wherein each ASIC miner is arranged in its own housing, said housing having at least one air inlet of the inner chamber exclusively associated with it.

16. Mobile data center according to claim 14, comprising GPU miners, each GPU miner comprising a plurality of graphic cards arranged in parallel on a support, each GPU miner being directly connected to a plurality of air inlets of the inner chamber, in particular to two to four air inlets and preferably to three air inlets.

17. (canceled)

18. (canceled)

19. (canceled)

20. (canceled)

21. (canceled)

22. Mobile data center according to claim 1, further comprising one or more sensors for determining at least one of the temperature in said inner chamber, the temperature outside said container, the power consumption of the operating computing modules, the air pressure in said inner chamber, the air pressure outside said container, the speed of the propellers of the fans, the volume flow created by the fans, the humidity in said inner chamber or in an air inlet of said inner chamber, the humidity outside said container.

23. Mobile data center according to claim 1, further comprising automatically controllable throttle valves in at least some of the air inlets of the inner chamber and/or, if present, in the air intake opening of the air intake chamber, said control unit controlling the operation of said throttle valves.

24. (canceled)

25. (canceled)

26. (canceled)

27. (canceled)

28. A method of operating a mobile data center comprising a plurality of computing modules to be air-cooled, a container with an inner chamber for housing the plurality of computing modules, a plurality of air inlets to the inner chamber, at least two fans arranged for creating an air pressure gradient in the inner chamber, and piping arranged for guiding air through the inlets to the computing modules to be air-cooled, comprising a step of operating said at least two fans to create an air pressure gradient in said inner chamber causing ambient air to enter the inner chamber via said air inlets.

29. The method according to claim 28, comprising monitoring the operational status of each fan and increasing the volume flow of at least one of the at least two fans if the volume flow of at least one of the at least two fans drops.

30. The method according to claim 28, further comprising monitoring the air pressure gradient created by said fans and reversing the direction of operation of said fans for a limited time period when said air pressure gradient exceeds a predetermined threshold value.

31. (canceled)

32. (canceled)

33. The method according to claim 28, further comprising monitoring at least one of the following physical properties: temperature inside said inner chamber, temperature outside said container, air pressure in said inner chamber, air pressure outside said container, speed of the propellers of the fans, volume flow created by the fans, humidity in said inner chamber or in an air inlet of said inner chamber, humidity outside said container; and controlling at least one of the volume flow created by said fans and the current computing power performed by the computing modules taking into account the at least one monitored physical property.

34. The method according to claim 33, further comprising controlling throttle valves provided in at least some of the air inlets and/or in, if present, an air intake opening in the container for closing and opening said air inlets and/or said air intake opening.

35. (canceled)

36. (canceled)
